(19) United States
(12) Patent Application Publication
(10) Pub. No.: US 2024/0145640 A1
(43) Pub. Date: May 2, 2024

(54) PHOSPHOR PLATE AND LIGHT EMITTING DEVICE

(71) Applicant: DENKA COMPANY LIMITED, Tokyo (JP)

(72) Inventors: Yuki KUBOTA, Tokyo (JP); Taiyo YAMAURA, Tokyo (JP); Kazuhiro ITO, Tokyo (JP)

(73) Assignee: DENKA COMPANY LIMITED, Tokyo (JP)

(21) Appl. No.: 18/280,418

(22) PCT Filed: Feb. 21, 2022
(86) PCT No.: PCT/JP2022/006930

§ 371 Date: Sep. 5, 2023

(30) Foreign Application Priority Data
Mar. 22, 2021 (JP) 2021-047097

(51) Int. Cl. H01L 33/50; C09K 11/02; C09K 11/77

(52) U.S. Cl. CPC H01L 33/502; C09K 11/02; C09K 11/77348; H01L 33/505

(57) ABSTRACT

A phosphor plate according to the present invention is a phosphor plate including: a plate-like composite including a base material and a phosphor dispersed in the base material, in which both Ry₁ and Ry₂ are 5.00 μm or less, where Ry₁ is a maximum height on a front surface of the phosphor plate and Ry₂ is a maximum height on a back surface.

### TECHNICAL FIELD

The present invention relates to a phosphor plate and a light emitting device.

### BACKGROUND ART

Various developments have been made so far on phosphor plates. As this kind of technique, for example, the technique described in Patent Document 1 is known. Patent Document 1 describes a wavelength conversion member in which an inorganic phosphor is dispersed in a glass matrix (claim 1 of Patent Document 1). According to the same Document, it is described that a shape of the wavelength conversion member is not limited and may be plate-like (paragraph 0054).

### RELATED DOCUMENT

### Patent Document

[Patent Document 1] Japanese Unexamined Patent Publication No. 2015-199640

### SUMMARY OF THE INVENTION

### Technical Problem

However, as a result of the examination by the present inventors, it has been found that there is room for improvement in terms of light emission characteristics in the plate-like wavelength conversion member described in Patent Document 1 described above.

### Solution to Problem

The present inventors have further conducted studies, and found that the light emission characteristics can be improved by increasing the smoothness of an excitation light incident surface and an excitation light emitting surface of a phosphor plate. As a result of further intensive studies based on such findings, the present inventors have found that with the use of a maximum height Ry, which means an interval between the highest peak top and the deepest peak bottom in a roughness curve representing the surface roughness profile as smoothness, light emission characteristics of a phosphor plate can be improved by adjusting the maximum height Ry on an incident surface and an emitting surface to a predetermined value or less, and completed the present invention.

According to the present invention, there is provided
a phosphor plate including: a plate-like composite including a base material and a phosphor dispersed in the base material,
in which both Ry₁ and Ry₂ are 5.00 μm or less, where Ry₁ is a maximum height on a front surface of the phosphor plate and Ry₂ is a maximum height on a back surface.

In addition, according to the present invention, there is provided
a light emitting device including: a light emitting element; and
the phosphor plate provided over one surface of the light emitting element.

### Advantageous Effects of Invention

The present invention is to provide a phosphor plate having excellent light emission characteristics and a light emitting device using the phosphor plate.

### BRIEF DESCRIPTION OF THE DRAWINGS

FIG. 1 is a schematic view showing an example of a configuration of a phosphor plate according to the present embodiment.

FIG. 2 (a) is a cross-sectional view schematically showing a configuration of a flip-chip type light emitting device, and (b) is a cross-sectional view schematically showing a configuration of a wire bonding type light emitting element.

FIG. 3 is a schematic view of a device for measuring light emission characteristics of the phosphor plate.

### DESCRIPTION OF EMBODIMENTS

Hereinafter, embodiments of the present invention will be described using the drawings. In addition, in all the drawings, the same constituent elements are denoted by the same reference signs, and description thereof will not be repeated. In addition, the drawings are schematic views, and dimensional ratios in the drawings are different from actual dimensional ratios.

A phosphor plate according to the present embodiment will be outlined.

An outline of the phosphor plate according to the present embodiment will be described.

The phosphor plate according to the present embodiment includes a plate-like composite including a base material and a phosphor dispersed in the base material.

The phosphor plate is configured so that both Ry₁ and Ry₂ are 5.00 μm or less, where Ry₁ is a maximum height on a front surface and Ry₂ is a maximum height on a back surface.

The phosphor plate can function as a wavelength converter which converts irradiated blue light into orange light and emits the orange light.

When the phosphor plate is used as a wavelength converter, a back surface of the phosphor plate is a light incident surface, and a front surface of the phosphor plate is a light emitting surface.

According to the findings of the present inventors, light emission characteristics can be stably evaluated by using a maximum height Ry on the front surface and the back surface of the phosphor plate as an index. Furthermore, as a result of further studies, it has been found that the light emission characteristics can be improved by adjusting the maximum height Ry on the front surface and the back surface to the above-described upper limit or less.

The upper limit of the maximum height Ry₁ on the front surface of the phosphor plate is 5.00 μm or less, preferably 3.00 μm or less, and more preferably 2.00 μm or less. Accordingly, it is possible to improve the light emission characteristics of the phosphor plate.

The lower limit of the above-described Ry₁ is not particularly limited, but may be a detection limit. The lower limit may be 0.10 μm or more, and is preferably 0.30 μm or more, and more preferably 0.50 μm or more. Accordingly, it is possible to improve the manufacturing stability of the phosphor plate.

The upper limit of the maximum height Ry₂ on the back surface of the phosphor plate is 5.00 μm or less, preferably 3.00 μm or less, more preferably 2.00 μm or less, and even more preferably 1.00 μm or less. Accordingly, it is possible to improve the light emission characteristics of the phosphor plate.

The lower limit of the above-described Ry₂ is not particularly limited, but may be a detection limit. The lower limit may be 0.10 μm or more, and is preferably 0.30 μm or more, and more preferably 0.50 μm or more. Accordingly, it is possible to improve the manufacturing stability of the phosphor plate.

According to one aspect of the phosphor plate, the phosphor plate may be configured so that at least one of the above-described Ry₁ and Ry₂ is 3.00 μm or less, preferably at least one of Ry₁ and Ry₂ is 3.00 μm or less and Ry₁>Ry₂ is satisfied, and more preferably Ry₁ and Ry₂ are 2.80 μm or less. Accordingly, it is possible to suppress the leakage of excitation light.

In addition, according to another aspect of the phosphor plate, the phosphor plate may be configured so that the following condition A1 and/or condition A2 are satisfied. Accordingly, it is possible to further suppress the leakage of excitation light.
Condition A1: The absolute value of a difference between the above-described Ry₁ and Ry₂ is 1.10 μm or less.
Condition A2: At least one of the above-described Ry₁ and Ry₂ is 0.90 μm or less.

In addition, according to a further aspect of the phosphor plate, the phosphor plate may be configured so that the following condition B1 or condition B2 is satisfied. As a result, it is possible to further improve the light emission characteristics of the phosphor plate.
Condition B1: The absolute value of a difference between the above-described Ry₁ and Ry₂ is 1.60 μm or less.
Condition B2: The absolute value of a difference between the above-described Ry₁ and Ry₂ is more than 1.60 μm and equal to or less than 1.90 μm, and Ry₁>Ry₂ is satisfied.

In the present embodiment, the above-described Ry₁ and Ry₂ can be controlled by appropriately selecting, for example, a type or a blending amount of each component contained in the phosphor plate, a manufacturing method of the phosphor plate, and the like. Among these, grinding and/or polishing the front surface and the back surface of the phosphor plate using a grindstone or abrasive particles of a predetermined particle size is exemplified as an element for adjusting the above-described Ry₁ and Ry e in a desired numerical range.

In a case in which the phosphor plate is irradiated with blue light having a wavelength of 455 nm, it is preferable that the peak wavelength of the wavelength conversion light radiated from the phosphor plate be 585 nm or more and 605 nm or less. In addition, according to this, by combining the phosphor plate and the light emitting element which emits the blue light, it is possible to obtain a light emitting device which emits an orange color having high luminance.

A configuration of the phosphor plate according to the present embodiment will be described in detail.

(Base Material)

In the composite constituting the phosphor plate, a phosphor and a base material formed of an inorganic material are in a mixed state. Specifically, a structure in which a phosphor is dispersed in a sintered material of a compound constituting an inorganic base material may be adopted. The phosphor may be uniformly dispersed in the inorganic base material in a particle state.

The base material may be a main component in the composite. In this case, a content of the base material may be, for example, 50 vol % or more, and preferably 60 vol % or more in terms of volume with respect to the composite.

The base material may be formed of a sintered material of a metal oxide including at least one of a sintered material of Al₂O₃, a sintered material of SiO₂, and a sintered material containing a spinel-based compound M₂ₓAl₄₋₄ₓO₆₋₄ₓ (where M is at least any of Mg, Mn, and Zn, and 0.2<x<0.6). These may be used alone, or two or more thereof may be used in combination. Among these, the base material may be formed of a sintered material containing alumina or a spinel-based compound from the viewpoint of heat characteristics and transparency.

Since the sintered material of Al₂O₃ absorbs less visible light, the emission intensity of the phosphor plate can be enhanced. In addition, since the sintered material of Al₂O₃ has high thermal conductivity, the heat resistance of the phosphor plate can be improved. Moreover, since the sintered material of Al₂O₃ is also excellent in mechanical strength, the durability of the phosphor plate can be enhanced.

The sintered material of SiO₂ may be formed of a glass matrix. Silica glass or the like is used as the glass matrix.

The sintered material containing the spinel-based compound is usually obtained by mixing a powder of a metal oxide represented by a general formula MO (M is at least any of Mg, Mn, and Zn) and a powder of Al₂O₃ and sintering the mixture.

Stoichiometrically, spinel has a composition represented by x=0.5 (that is, general formula MAl₂O₄).

Note that, depending on a ratio between the amount of MO and the amount of Al₂O₃, which are raw materials, a spinel-based compound having a non-stoichiometric composition in which MO or Al₂O₃ is excessively solid-dissolved is provided.

A sintered body containing a spinel-based compound represented by the general formula is relatively transparent. Therefore, excessive scattering of light in the phosphor plate is suppressed. Furthermore, from the viewpoint of transparency, it is preferable that a spinel-based compound in which M is Mg in the general formula be used.

(Phosphor)

The phosphor contained in the composite may include, for example, one or more selected from the group consisting of a SiAlON phosphor, a CASN phosphor, and a SCASN phosphor. Examples of the SiAlON phosphor include an α-SiAlON phosphor.

The cx-SiAlON phosphor includes an cx-SiAlON phosphor containing an Eu element represented by General Formula (1).

(M)_{m(1-x)/p}(Eu)_{mx/2}(Si)₁₂₋₍ₘ₊ₙ₎(Al)ₘ₊ₙ(O)ₙ(N)₁₆₋ₙ General Formula (1)

In General Formula (1), M represents one or more elements selected from the group consisting of Li, Mg, Ca, Y, and a lanthanide element (excluding La and Ce), and p represents a valence of an M element. 0<x<0.5, 1.5≤m≤4.0, and 0≤n≤2.0 are satisfied. n may be 2.0 or less, 1.0 or less, or 0.8 or less, for example. In general, a phosphor in which M is Ca is called a Ca-α-SiAlON phosphor.

In a solid solution composition of the α-SiAlON, m Si—N bonds of a unit cell (Si₁₂N₁₆) of α-silicon nitride are substituted with Al—N bonds, and n Si—N bonds thereof are substituted with Al—O bonds, m/p cations (M, Eu) invade and are solid-dissolved into a crystal lattice in order to maintain electrical neutrality, and it is represented by the above-described general formula. In particular, in a case in which Ca is used as M, the α-SiAlON is stabilized in a wide composition range, and by substituting a part of the Ca elements with Eu serving as a luminescent center, excitation occurs by light in a wide wavelength range from ultraviolet to blue light, whereby a phosphor emitting of visible light ranging from yellow to orange light can be obtained.

Since α-SiAlON has a second crystal phase different from the α-SiAlON or an amorphous phase that is inevitably present, the solid solution composition of the α-SiAlON cannot be strictly defined by composition analysis or the like. The α-SiAlON may include, as another crystal phase, β-SiAlON, aluminum nitride or its polytypoids, Ca₂Si₅N₈, CaAlSiN₃, and the like.

As a manufacturing method of the α-SiAlON phosphor, there is a method in which a mixed powder consisting of a compound of silicon nitride, aluminum nitride, and an interstitial solid solution element is heated and reacted in a high temperature nitrogen atmosphere. In a heating step, a part of the constituent components forms a liquid phase, and an cx-SiAlON solid solution is generated due to the movement of the substance to the liquid phase. In the cx-SiAlON phosphor after synthesis, a plurality of equiaxed primary particles are sintered to form massive secondary particles. The primary particles in the present embodiment refer to the smallest particles having the same crystal orientation in the particles and capable of being present independently.

As the CASN phosphor, for example, a phosphor obtained by activating an Eu element in a host crystal of alkaline-earth silicon nitride represented by CaAlSiN₃ is used.

As the SCASN phosphor, for example, a phosphor obtained by activating an Eu element in a host crystal of alkaline-earth silicon nitride represented by (Sr, Ca)AlSiN₃ is used.

The lower limit of an average particle diameter of the phosphor is, for example, preferably 1 μm or more, and more preferably 2 μm or more. As a result, it is possible to enhance the emission intensity. In addition, the upper limit of the average particle diameter of the phosphor is preferably 30 μm or less, and more preferably 20 μm or less. The average particle diameter of the phosphor is a dimension of the secondary particles. By setting the average particle diameter to 5 μm or more, it is possible to further enhance the transparency of the composite. Meanwhile, by setting the average particle diameter of the phosphor to 30 μm or less, it is possible to suppress the occurrence of chipping in a case in which the phosphor plate is cut with a dicer or the like.

Here, the average particle diameter of the phosphor refers to a particle diameter D50 of 50% of a passing amount integration (integrated passing amount ratio) from a small particle diameter side in a volume-based particle diameter distribution obtained by measurement by a laser diffractive scattering type particle diameter distribution measurement method (LS13-320 manufactured by Beckman Coulter, Inc).

The lower limit value of a content of the phosphor is, for example, vol % or more, preferably 10 vol % or more, and more preferably 15 vol % or more in 100 vol % of the composite. As a result, it is possible to enhance the emission intensity of the thin phosphor plate. In addition, it is possible to improve the light conversion efficiency of the phosphor plate.

Meanwhile, the upper limit value of the content of the phosphor is, for example, 60 vol % or less, preferably 50 vol % or less, and more preferably 40 vol % or less in 100 vol % of the composite. As a result, it is possible to suppress a decrease in thermal conductivity of the phosphor plate.

In the phosphor plate, the upper limit value of a light transmittance for blue light of 450 nm is, for example, 10% or less, preferably 5% or less, and more preferably 1% or less. As a result, it is possible to suppress the blue light transmitted through the phosphor plate, so that it is possible to increase emission luminance. By appropriately adjusting the content of the phosphor or the thickness of the phosphor plate, the light transmittance for blue light of 450 nm can be reduced.

The lower limit value of the light transmittance for blue light of 450 nm is not particularly limited, but may be, for example, 0.01% or more. As a result, it is possible to further enhance the emission intensity.

A manufacturing process of the phosphor plate according to the present embodiment will be described in detail.

A manufacturing method of the phosphor plate according to the present embodiment may include a step (1) of obtaining a mixture containing a metal oxide and a phosphor, and a step (2) of firing the obtained mixture.

In addition, in the manufacturing method of the phosphor plate, the metal oxide may be melted, and the particles of the phosphor may be mixed in the obtained melt.

In the step (1), it is preferable that the powder of the phosphor or the metal oxide used as raw materials have high purity as much as possible, and the impurities of elements other than the constituent elements are preferably 0.1% or less, and more preferably 0.01% or less.

Various dry and wet methods can be applied to the mixing of the raw material powder, but a method is preferable in which the phosphor particles used as the raw material are not pulverized as much as possible and the impurities from the device are not mixed as much as possible during mixing.

As the metal oxide which is the phosphor raw material, a material including at least one of an Al₂O₃ powder, a SiO₂ powder, and a spinel raw material powder may be used. These may be used alone, or two or more thereof may be used in combination.

The metal oxide may be a fine powder, and an average particle diameter thereof may be, for example, 1 μm or less.

An alumina powder (Al₂O₃) may be used as the metal oxide which is the raw material.

The upper limit of a BET specific surface area of the alumina powder is, for example, 10.0 m²/g or less, preferably 9.0 m²/g or less, more preferably 8.0 m²/g or less, and still more preferably 6.0 m²/g or less. As a result, it is possible to suppress the blackening of the phosphor plate. Meanwhile, the lower limit of the BET specific surface area of the alumina powder is, for example, 0.1 m²/g or more, preferably 0.5 m²/g or more, more preferably 1.0 m²/g or more, and still more preferably 2.0 m²/g or more. As a result, it is possible to enhance the sinterability of the alumina powder and to form a dense composite.

In the step (2), the mixture of the alumina powder and the phosphor powder may be fired at 1,300° C. or higher and 1,650° C. or lower, for example. The heating temperature in the sintering step is more preferably 1,500° C. or higher and 1,600° C. or lower. In order to densify the composite, it is preferable that the firing temperature be high. However, in a case in which the firing temperature is too high, the phosphor reacts with the alumina and the emission intensity of the phosphor plate is decreased. Accordingly, the firing temperature is preferably in the above-described range.

In addition, in a case in which the firing temperature is in a high temperature region of about 1, 600° C. to 1, 650° C., a maintaining time for maintaining this temperature is, for example, 20 minutes or shorter, and preferably 15 minutes or shorter. As a result, it is possible to enhance the emission intensity of the phosphor plate.

A glass powder (powder containing SiO₂) may be used as the metal oxide which is the raw material.

As the glass powder, a SiO₂ powder (silica powder) or a general glass raw material can be used. These may be used alone, or two or more thereof may be used in combination.

A spinel raw material powder may be used as the metal oxide which is the raw material.

Here, the “spinel raw material powder” is, for example, (i) a powder containing a spinel represented by the general formula M₂ₓAl₄₋₄ₓO₆₋₄ₓ described above, and/or (ii) a mixture of a powder of a metal oxide represented by the general formula MO (M is at least any of Mg, Mn, and Zn) and an Al₂O₃ powder.

In the step (2), the spinel raw material powder may be fired at, for example, 1,300° C. or higher and 1,650° C. or lower. The heating temperature in the sintering step is more preferably 1,500° C. or higher and 1,600° C. or lower. In order to densify the composite, it is preferable that the firing temperature be high. However, in a case in which the firing temperature is too high, the emission intensity of the phosphor plate is decreased. Accordingly, the firing temperature is preferably in the above-described range.

In addition, in a case in which the firing temperature is in a high temperature region of about 1, 600° C. to 1, 650° C., a maintaining time for maintaining this temperature is, for example, 20 minutes or shorter, and preferably 15 minutes or shorter. As a result, it is possible to enhance the emission intensity of the phosphor plate.

In the manufacturing method described above, a firing method may be normal pressure sintering or pressure sintering, but in order to suppress a decrease in characteristics of the phosphor and to obtain a dense composite, the pressure sintering, which is easier to make the composite denser than the normal pressure sintering, is preferable.

Examples of the pressure sintering method include hot press sintering, spark plasma sintering (SPS), and hot isotropic pressure (HIP) sintering. In the hot press sintering or SPS sintering, the pressure is 10 MPa or higher, and preferably 30 MPa or higher. In addition, the pressure is 100 MPa or lower, and preferably 80 MPa or lower.

A firing atmosphere is preferably a non-oxidizing inert gas, such as nitrogen or argon, or a vacuum atmosphere for the purpose of preventing the oxidation of the phosphor. From the above, the phosphor plate according to the present embodiment is obtained.

An appropriate surface treatment is performed on the front surface and the back surface of the obtained phosphor plate.

Examples of the surface treatment include grinding using a diamond grindstone or the like, and polishing such as lapping and polishing.

A light emitting device according to the present embodiment will be described.

The light emitting device according to the present embodiment includes a light emitting element and the above-described phosphor plate provided over one surface of the light emitting element.

A specific example of the light emitting device includes a group III nitride semiconductor light emitting element (light emitting element 20), and a phosphor plate 10 described above provided over one surface of the group III nitride semiconductor light emitting element. The group III nitride semiconductor light emitting element includes, for example, an n layer, a light emitting layer, and a p layer composed of a group III nitride semiconductor, such as an AlGaN-based, GaN-based, or InAlGaN-based material. As the group III nitride semiconductor light emitting element, a blue LED that emits blue light can be used.

The phosphor plate 10 may be disposed directly over one surface of the light emitting element 20, but can be disposed through a light transmitting member or a spacer.

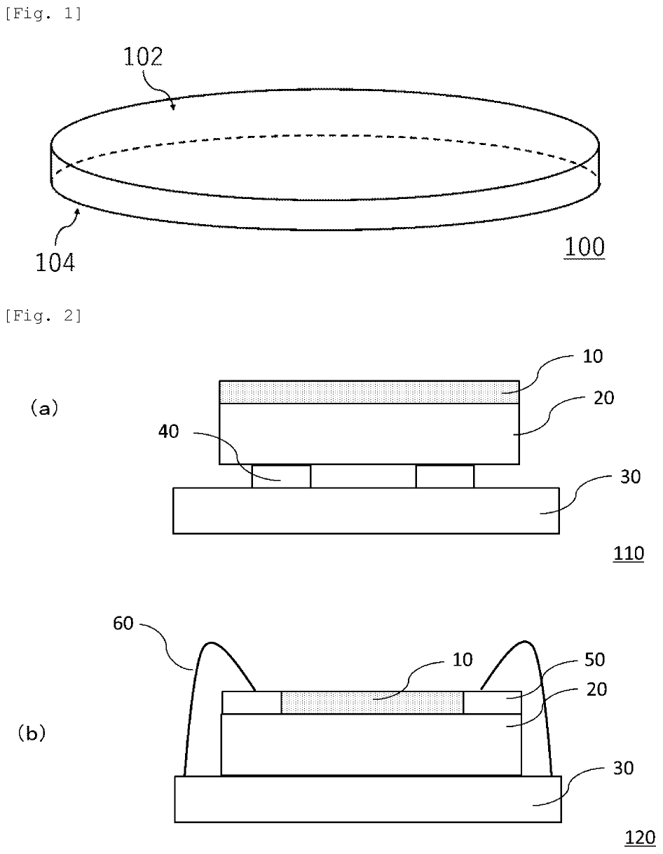

As the phosphor plate 10 disposed over the light emitting element 20, a disk-like phosphor plate 100 (phosphor wafer) shown in FIG. 1 may be used, but an individually separated phosphor plate 100 can be used.

FIG. 1 is a schematic view showing an example of a configuration of the phosphor plate. The thickness of the phosphor plate 100 shown in FIG. 1 can be appropriately set according to the intended use.

The lower limit of the thickness of the phosphor plate 100 shown in FIG. 1 is, for example, 0.050 mm or more, preferably 0.080 mm or more, and more preferably 0.100 mm or more. The upper limit of the thickness of the phosphor plate 100 is, for example, 1 mm or less, preferably 0.500 mm or less, and more preferably 0.300 mm or less. By setting the thickness to be in such a range, it is possible to improve the light extraction efficiency and to improve the emission intensity.

Since the occurrence of chipping or cracking at the corners is suppressed as compared with a case of a rectangular shape, the disk-like phosphor plate 100 is excellent in durability and transportability.

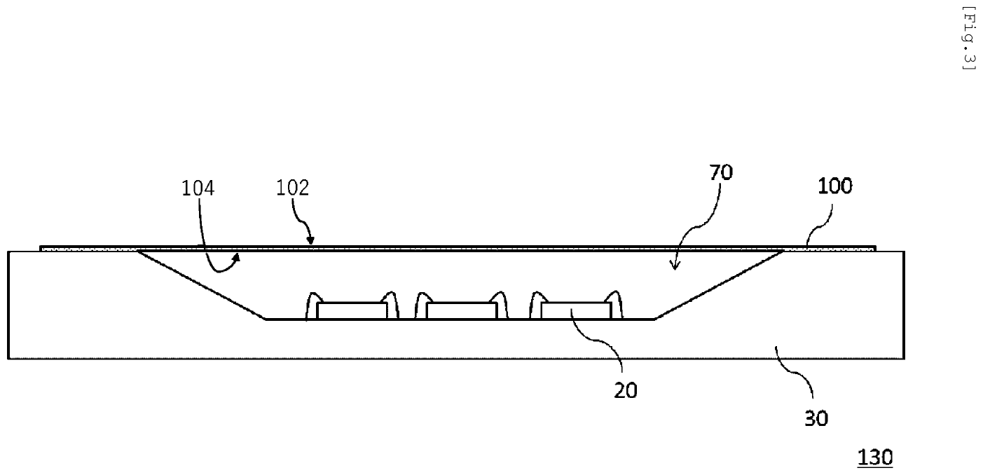

An example of the semiconductor device described above is shown in FIGS. 2(a) and 2(b). FIG. 2(a) is a cross-sectional view schematically showing a configuration of a flip-chip type light emitting device 110, and FIG. 2(b) is a cross-sectional view schematically showing a configuration of a wire bonding type light emitting device 120.

The light emitting device 110 of FIG. 2(a) has a substrate 30, a light emitting element 20 electrically connected to the substrate through a solder 40 (die bond material), and a phosphor plate 10 provided over a light emitting surface of the light emitting element 20. The flip-chip type light emitting device 110 may have any one of a face-up type structure and a face-down type structure.

In addition, the light emitting device 120 of FIG. 2(b) has a substrate 30, a light emitting element 20 electrically connected to the substrate 30 through a bonding wire 60 and an electrode 50, and a phosphor plate 10 provided over a light emitting surface of the light emitting element 20.

In FIG. 2, the light emitting element 20 and the phosphor plate are attached by a known method, and, for example, may be adhered by a silicone-based adhesive or a heat fusion method.

In addition, the light emitting device 110 and the light emitting device 120 may be entirely sealed with a transparent sealing material.

The individually separated phosphor plate 10 may be attached to the light emitting element 20 mounted on the substrate 30. A plurality of the light emitting elements 20 may be attached to the large-area phosphor plate 100, and then the light emitting elements with the phosphor plate 10 may be individually separated by dicing. In addition, the large-area phosphor plate 100 may be attached to a semiconductor wafer on which a plurality of the light emitting elements 20 are formed on a surface thereof, and then the semiconductor wafer and the phosphor plate 100 may be individually separated at a time.

The embodiments of the present invention have been described above; however, these are examples according to the present invention, and it is possible to adopt various configurations other than the above. In addition, the present invention is not limited to the embodiments described above and modifications, improvements, and the like are included in the present invention in a range in which it is possible to achieve the purpose of the present invention.

### EXAMPLES

<Manufacturing of Phosphor Plate>

As a raw material of a phosphor plate, an alumina powder (AA-03 (manufactured by Sumitomo Chemical Co., Ltd., BET specific surface area: 5.2 m²/g)) and a Ca-α SiAlON phosphor (ALONBRIGHT YL-600B, manufactured by Denka Company Limited., D50 is 15 μm) were used.

7.857 g of the alumina powder and 2.833 g of the Ca-α SiAlON phosphor powder were weighed and dry-mixed with an agate mortar. The mixed raw material was disaggregated through a nylon mesh sieve having an opening of 75 μm to obtain a raw material mixed powder. A blending ratio calculated from the true density of the raw materials (alumina: 3.97 g/cm³ and Ca-α SiAlON phosphor: 3.34 g/cm³) is alumina:Ca-α SiAlON phosphor=70:30 vol %.

A carbon dice having an inner diameter of 30 mm in which a carbon lower punch was set was filled with about 11 g of the raw material mixed powder, a carbon upper punch was set, and the raw material powder was interposed therebetween. A carbon sheet (GRAFOIL manufactured by GraTech) having a thickness of 0.127 mm was set between the raw material mixed powder and the carbon jig to prevent sticking.

A hot press jig filled with this raw material mixed powder was set in a multipurpose high temperature furnace (manufactured by Fuji Dempa Kogyo Co., Ltd., Hi multi 5000) including a carbon heater. An inside of the furnace was evacuated to 0.1 Pa or less, and the upper and lower punches were pressurized with a press pressure of 55 MPa while maintaining a reduced pressure state. While maintaining a pressurized state, the temperature was raised to 1,600° C. at a rate of 5° C. per minute. Heating was stopped immediately after the temperature reached 1,600° C., the temperature was slowly decreased to a room temperature, and the pressure was depressurized (firing step). After that, a fired material having an outer diameter of 30 mm was recovered.

A side surface of the recovered fired material was ground using a cylindrical grinder, and under the following conditions, grinding using a surface grinder and polishing using a grinder were performed to obtain a disk-like phosphor plate having a thickness (mm) as shown in Table 1 and a diameter of 25 mm.

(Conditions of Surface Grinding and Polishing in Each of Examples and Comparative Examples)

### Example 1

Front Surface and Back Surface: grinding with a diamond grindstone (#400)→polishing with 9 μm-diamond abrasive particles (polishing machine rotation speed 150 rpm, polishing time: 6 minutes)→polishing with 3 μm-diamond abrasive particles (polishing machine rotation speed 150 rpm, polishing time: 6 minutes)→polishing with 1 μm-diamond abrasive particles (polishing machine rotation speed: 150 rpm, polishing time: 3 minutes)

### Example 3

Front Surface: grinding with a diamond grindstone (#400)→polishing with 9 μm-diamond abrasive particles (polishing machine rotation speed 150 rpm, polishing time: 6 minutes)→polishing with 3 μm-diamond abrasive particles (polishing machine rotation speed 150 rpm, polishing time: 6 minutes)→polishing with 1 μm-diamond abrasive particles (polishing machine rotation speed: 150 rpm, polishing time: 3 minutes)
Back Surface: grinding with a diamond grindstone (#400)

### Example 5

Front Surface and Back Surface: grinding with a diamond grindstone (#400)

### Example 7

Front Surface: grinding with a diamond grindstone (#400)→polishing with 9 μm-diamond abrasive particles (polishing machine rotation speed 150 rpm, polishing time: 6 minutes)
Back Surface: grinding with a diamond grindstone (#400)

### Example 9

Front Surface: grinding with a diamond grindstone (#400)→polishing with 9 μm-diamond abrasive particles (polishing machine rotation speed 150 rpm, polishing time: 6 minutes)
Back Surface: grinding with a diamond grindstone (#400)→polishing with 9 μm-diamond abrasive particles (polishing machine rotation speed 150 rpm, polishing time: 6 minutes)→polishing with 3 μm-diamond abrasive particles (polishing machine rotation speed 150 rpm, polishing time: 6 minutes)→polishing with 1 μm-diamond abrasive particles (polishing machine rotation speed: 150 rpm, polishing time: 3 minutes)

### Comparative Example 1

Front Surface: grinding with a diamond grindstone (#400)→polishing with 9 μm-diamond abrasive particles (polishing machine rotation speed 150 rpm, polishing time: 6 minutes)→polishing with 3 μm-diamond abrasive particles (polishing machine rotation speed 150 rpm, polishing time: 6 minutes)→polishing with 1 μm-diamond abrasive particles (polishing machine rotation speed: 150 rpm, polishing time: 3 minutes)
Back Surface: grinding with a diamond grindstone (#200)

### Comparative Example 3

Front Surface: grinding with a diamond grindstone (#400)
Back Surface: grinding with a diamond grindstone (#200)

### Example 2

The phosphor plate of Example 1 was turned upside down and used.

### Example 4

The phosphor plate of Example 3 was turned upside down and used.

### Example 6

The phosphor plate of Example 5 was turned upside down and used.

### Example 8

The phosphor plate of Example 7 was turned upside down and used.

### Example 10

The phosphor plate of Example 9 was turned upside down and used.

### Comparative Example 2

The phosphor plate of Comparative Example 1 was turned upside down and used.

### Comparative Example 4

The phosphor plate of Comparative Example 3 was turned upside down and used.

Ry₁ on the front surface and Ry e on the back surface of the phosphor plate were measured using a surface roughness measuring device (SJ-400 manufactured by Mitutoyo Corporation) in accordance with JIS B 0031: 1994

TABLE 1

| | | | | | Emission | |
|---|---|---|---|---|---|---|
| | | | | | Intensity | |
| | | | | | (Total | Leakage of |
| | | Thickness | Ry₁ Front | Ry₂ Back | Luminous | Excitation |
| | Sample No. | (mm) | (μm) | (μm) | Flux) | Light |
| Example 1 | 1 | 0.232 | 0.70 | 0.62 | 100.0% | 3.2% |
| Example 2 | | | 0.62 | 0.70 | 99.8% | 3.3% |
| Comparative | 2 | 0.225 | 0.82 | 5.58 | 95.2% | 3.9% |
| Example 1 | | | | | | |
| Comparative | | | 5.58 | 0.82 | 97.4% | 3.8% |
| Example 2 | | | | | | |
| Example 3 | 3 | 0.227 | 0.72 | 2.58 | 97.9% | 3.6% |
| Example 4 | | | 2.58 | 0.72 | 100.0% | 3.5% |
| Example 5 | 4 | 0.231 | 2.63 | 2.67 | 98.4% | 3.4% |
| Example 6 | | | 2.67 | 2.63 | 98.0% | 3.2% |
| Comparative | 5 | 0.226 | 3.03 | 6.48 | 94.9% | 4.0% |
| Example 3 | | | | | | |
| Comparative | | | 6.48 | 3.03 | 95.8% | 3.6% |
| Example 4 | | | | | | |
| Example 7 | 6 | 0.223 | 1.85 | 3.35 | 98.9% | 4.0% |
| Example 8 | | | 3.35 | 1.85 | 100.5% | 3.8% |
| Example 9 | 7 | 0.231 | 1.82 | 0.82 | 100.4% | 3.6% |
| Example 10 | | | 0.82 | 1.82 | 100.2% | 3.6% |

The obtained phosphor plates were evaluated based on the evaluation items described below.

[Evaluation of Optical Characteristics]

The emission intensity of the phosphor plate obtained in each of Examples and Comparative Examples was measured in accordance with the following procedure.

Optical characteristics of the phosphor plate were measured by using a chip-on-board type (COB type) LED package 130. FIG. 3 is a schematic view of a device (LED package 130) for measuring an emission spectrum of the phosphor plate 100.

First, the phosphor plate 100 of each of Examples and Comparative Examples and an aluminum substrate (substrate 30) on which a recess portion 70 were formed was prepared. A diameter φ of a bottom surface of the recess portion 70 was set to 13.5 mm, and a diameter φ of an opening portion of the recess portion 70 was set to 16 mm.

Next, a blue LED (light emitting element 20) was mounted as a blue light emitting light source inside the recess portion 70 of the substrate 30.

Thereafter, the circular phosphor plate 100 was installed above the blue LED so as to close the opening portion of the recess portion 70 of the substrate 30 to manufacture the device (chip-on-board type (COB type) LED package 130) shown in FIG. 3.

The emission spectrum on the surface of the phosphor plate 100 when the blue LED of the manufactured LED package 130 was turned on was measured by using a total luminous flux measurement system (HalfMoon/φ1000 mm integrating sphere system, manufactured by OTSUKA ELECTRONICS CO., LTD).

In the obtained emission spectrum, a maximum value (W/nm) of the emission intensity of orange light (orange) having a wavelength of 585 nm or more and 605 nm was obtained. Table 1 shows relative values (%) of other Examples and Comparative Examples with reference to the maximum value of the emission intensity of the orange light in Example 1 regarded as 100%.

When the maximum value of the emission intensity of the orange light (orange) having a wavelength of 585 nm or more and 605 nm in the emission spectrum is represented by T₀, and the maximum value of the emission intensity of the blue light (blue) having a wavelength of 445 nm or more and 465 nm is represented by T_{B}, the transmission amount of the blue light (leakage of excitation light) from the blue LED was defined as T_{B}/T_{O}×100 and calculated. The results are shown in Table 1.

The results showed that the phosphor plates of Examples 1 to have more excellent emission intensity than Comparative Examples 1 to 4.

In addition, the results showed that in Examples 1 to 6, 9, and 10, the transmission of blue light, which is excitation light, is further suppressed than in Examples 7 and 8, and that in Examples 1, 2, and 4 to 10, the emission intensity is improved than in Example 3.

It was found that the phosphor plates of Examples have excellent light emission characteristics.

This application claims priority to Japanese Patent Application No. 2021-047097 filed on Mar. 22, 2021, incorporated herein by reference in its entirety.

### REFERENCE SIGNS LIST

10 phosphor plate
20 light emitting element
30 substrate
40 solder
50 electrode
60 bonding wire
70 recess portion
100 phosphor plate
102 front surface
104 back surface
100 light emitting device
120 light emitting device
130 LED package

1. A phosphor plate comprising:
a plate-like composite including a base material and a phosphor dispersed in the base material,
wherein both Ry₁ and Ry₂ are 5.00 μm or less, where Ry₁ is a maximum height on a front surface of the phosphor plate and Ry₂ is a maximum height on a back surface.

2. The phosphor plate according to claim 1,
wherein at least one of Ry₁ and Ry₂ is 3.00 μm or less.

3. The phosphor plate according to claim 1,
wherein the base material contains alumina or a spinel-based compound.

4. The phosphor plate according to claim 1,
wherein the phosphor includes one or more selected from the group consisting of a SiAlON phosphor, a CASN phosphor, and a SCASN phosphor.

5. The phosphor plate according to claim 1,
wherein a content of the phosphor is 5 vol % or more and 60 vol % or less in 100 vol % of the composite.

6. The phosphor plate according to claim 1,
wherein a plate thickness is 0.050 mm or more and 1 mm or less.

7. A light emitting device comprising:
a light emitting element; and
the phosphor plate according to claim 1 provided over one surface of the light emitting element.
